(19) United States
(12) Patent Application Publication
(10) Pub. No.: US 2015/0144963 A1
(43) Pub. Date: May 28, 2015

(54) SILICON CARBIDE EPI-WAFER AND METHOD OF FABRICATING THE SAME

(71) Applicant: LG INNOTEK CO., LTD., Seoul (KR)

(72) Inventor: SeokMin Kang, Seoul (KR)

(21) Appl. No.: 14/404,462

(22) PCT Filed: May 30, 2013
(86) PCT No.: PCT/KR2013/004757

§ 371 Date: Nov. 27, 2014

(30) Foreign Application Priority Data
May 31, 2012 (KR) 10-2012-0058854

(51) Int. Cl. H01L 29/16

(52) U.S. Cl. CPC H01L 29/1608
USPC 257/77

(57) ABSTRACT

A method of fabricating an epi-wafer includes providing a wafer in a susceptor, and growing an epi-layer on the wafer. The growing of the epi-layer on the wafer includes a first process of supplying a first input quantity of a raw material to the susceptor, and a second process of supplying a second input quantity of the raw material to the susceptor. The first input quantity is smaller than the second input quantity. An epi-wafer includes a wafer and an epi-layer formed on the wafer. Surface defects of the wafer are 1 ea/cm² or less.

### TECHNICAL FIELD

The present invention relates to a silicon carbide epi-wafer and a method of fabricating the same.

### BACKGROUND ART

Generally, among technology for forming various thin films on a substrate or a wafer, a chemical vapor deposition (CVD) method has been widely used. The CVD method is a deposition technique accompanied by a chemical reaction, in which a semiconductor thin film or an insulating layer may be formed on a surface of a wafer using a chemical reaction of a source material.

Such a CVD method and a CVD deposition apparatus have attracted attention as an important technology for forming a thin film due to reduction in size of semiconductor devices and development of high efficiency and high power LEDs. The CVD method and the CVD deposition apparatus are currently used to deposit various thin films such as a silicon layer, an oxide layer, a silicon nitride layer, or silicon oxynitride layer on a wafer.

For example, in order to deposit a silicon carbide thin film on a substrate or a wafer, a reaction gas capable of reacting with the wafer needs to be supplied. Conventionally, a silicon carbide epi-layer is deposited by supplying a gas material, such as a standard precursor like silane (SiH₄) or ethylene (C₂H₄), or a liquid material such as methyltrichlorosilane (MTS), heating the material to generate an intermediate compound, such as CH₃ or SiClₓ, and supplying the intermediate compound into a deposition unit to react the intermediate compound with a wafer disposed in a susceptor.

However, when the epi-layer is deposited on the silicon carbide, problems such as defects or surface roughness may be generated on the wafer. The defects or the surface roughness of the wafer may degrade quality of the silicon carbide epi-wafer.

Accordingly, a silicon carbide epi-wafer capable of solving the problems such as defects or surface roughness, and a method of fabricating the silicon carbide epi-wafer need to be developed.

### DISCLOSURE

### Technical Problem

The present invention is directed to a method of fabricating an epi-wafer by which a high quality silicon carbide epi-wafer is fabricated by reducing surface defects and/or surface roughness of a wafer, and an epi-wafer fabricated by the method.

### Technical Solution

According to an aspect of the present invention, there is provided a method of fabricating an epi-wafer including providing a wafer in a susceptor and growing an epi-layer on the wafer. The growing of the epi-layer on the wafer includes a first process of supplying a first input quantity of a raw material to the susceptor, and a second process of supplying a second input quantity of the raw material to the susceptor. The first input quantity is smaller than the second input quantity.

According to another other aspect of the present invention, there is provided a method of fabricating an epi-wafer in which the amount of a raw material supplied into a susceptor is controlled to have different growth rates in a first process and in a second process.

According to still another other aspect of the present invention, there is provided an epi-wafer including a wafer, a first epi-layer formed on the wafer, and a second epi-layer formed on the first epi-layer. Surface defects of the epi-wafer are 1 ea/cm² or less.

### Advantageous Effects

According to the embodiments of the present invention, surface defects can be decreased by reducing an input quantity of a raw material to reduce a growth rate in a first process compared to a normal growth process. Then, an epi-layer may be deposited in a second process. Thus surface defects on the final silicon carbide epi wafer may be decreased.

Accordingly, the final silicon carbide epi-wafer fabricated by the method of fabricating an epi-wafer according to the embodiment of the present invention may have reduced surface defects and high quality.

Further the surface defects of the silicon carbide epi-wafer according to the embodiment of the present invention may be about 1 ea/cm².

### DESCRIPTION OF DRAWINGS

The above and other objects, features, and advantages of the present invention will become more apparent to those of ordinary skill in the art by describing in detail exemplary embodiments thereof with reference to the accompanying drawings, in which:

FIG. 1 is a process flowchart for describing a method of fabricating an epi-wafer according to an embodiment of the present invention; and

FIGS. 2 to 4 are respectively an exploded perspective view, a perspective view, and a cross-sectional view of a susceptor for describing a method of fabricating an epi-wafer according to an embodiment of the present invention, wherein FIG. 2 is a exploded perspective view of a deposition apparatus according to an embodiment of the present invention, FIG. 3 is a perspective view of a deposition apparatus according to an embodiment of the present invention, and FIG. 4 is a part of a cross-sectional view taken along line of FIG. 3.

### MODE FOR INVENTION

Exemplary embodiments of the present invention will be described in, detail below with reference to the accompanying drawings. While the present invention is shown and described in connection with exemplary embodiments thereof, it will be apparent to those skilled in the art that various modifications can be made without departing from the spirit and scope of the invention.

It will be understood that when a layer, region, pattern, or structure is referred to as being “on” or “under” another layer, region, pattern, or structure, it can be directly on or under the other element or intervening elements may be present. Spatially relative terms, such as “beneath,” “below,” “lower,” “above,” “upper,” and the like may be used herein to describe the relationship of one element or feature to another, as illustrated in the drawings.

In the drawings, the thicknesses or sizes of layers, regions, patterns, or structures may be modified for clarity and convenience of descriptions.

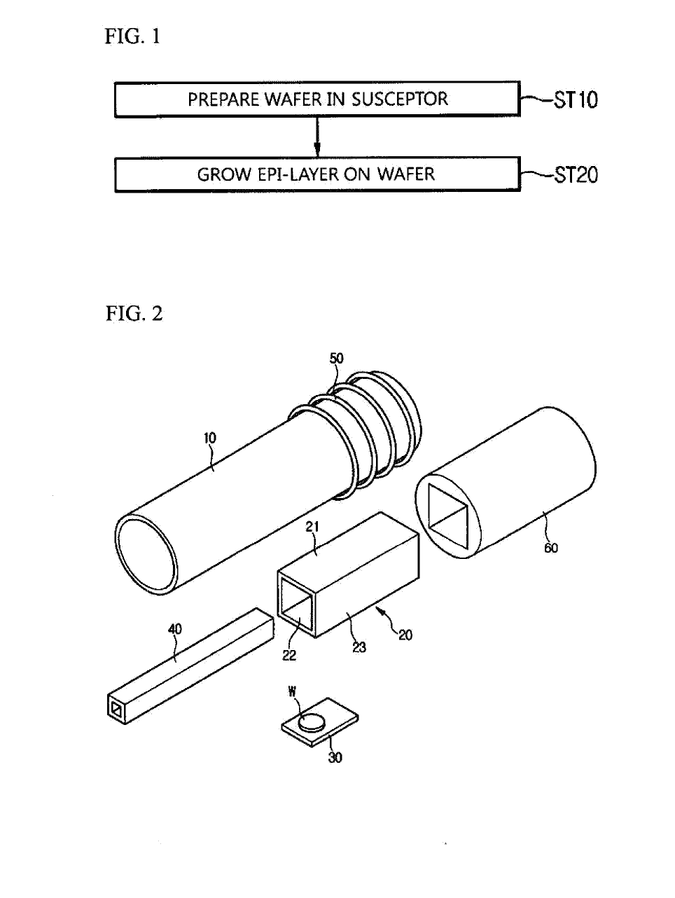

Hereinafter, an epi-wafer and a method of fabricating an epi-wafer according to an embodiment of the present invention will be described with reference to FIGS. 1 to 4.

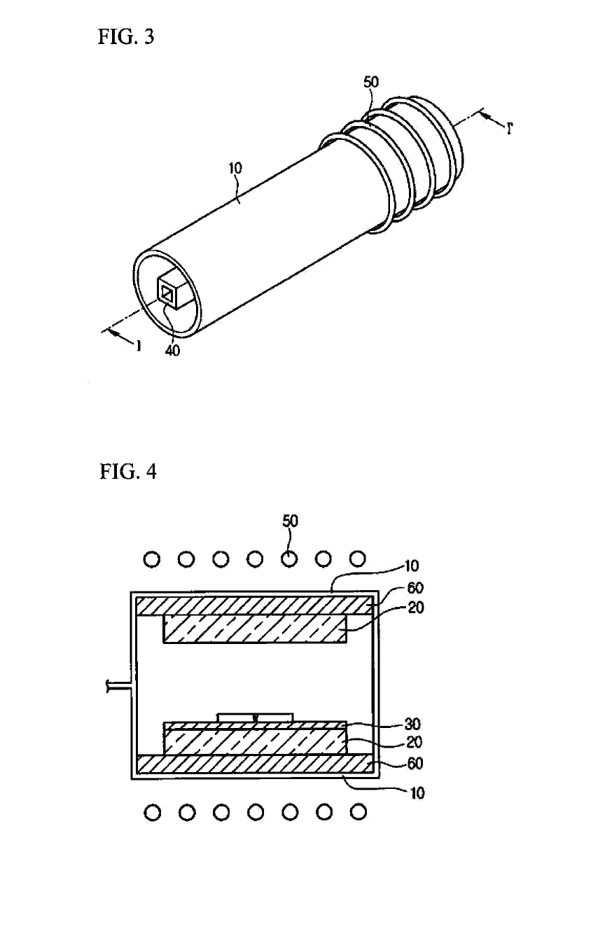

FIG. 1 is a process flowchart for describing a method of fabricating an epi-wafer according to an embodiment of the present invention, and FIGS. 2 to 4 are respectively an exploded perspective view, a perspective view, and a cross-sectional view of a susceptor, for describing a method of fabricating an epi-wafer according to the embodiment of the present invention.

Referring to FIG. 1, the method of fabricating an epi-wafer according to the embodiment of the present invention may include providing a wafer in a susceptor (ST10) and growing an epi-layer on the wafer (ST20).

In a process of providing the wafer in the susceptor (ST10), the wafer may be disposed in the susceptor disposed in a chamber. Here, the wafer may be a silicon carbide wafer. That is, the method of fabricating an epi-wafer according to the embodiment of the present invention may be a method of fabricating a silicon carbide epi-wafer.

Next, in the process of growing the epi-layer on the wafer (ST20), a raw material may be supplied in the susceptor to grow a silicon carbide epi-layer on the wafer.

The process of growing the epi-layer on the wafer (ST20) may be divided into two processes. More specifically, the process of growing the epi-layer on the wafer (ST20) includes a first process in which a first input quantity of the raw material is supplied to the susceptor, and a second process in which a second input quantity of the raw material is supplied to the susceptor.

The first process and the second process may be divided according to the amount of the raw material supplied to the susceptor. That is, the amount of the raw material supplied to the susceptor in the first process may be different from that in the second process. More specifically, the amount of the raw material supplied in the first process may be smaller than that in the second process.

The amount of the raw material supplied in the first process may be 1/10 of that in the second process, or less. That is, a flux of the raw material supplied in the first process may be 1/10 of that supplied in the second process, or less. The flux of the raw material supplied in the first process may be in the range of 1/10 to ½ of that supplied in the second process.

The first process and the second process may be successively carried out. That is, the first process and the second process may not be separate processes but may be a continuous process.

The raw material supplied to the susceptor may include carbon (C), silicon (Si), chloride (Cl), and hydrogen (H). More specifically, the raw material may include a liquid, gas, or solid material including C and Si. The liquid material may include methyltrichlorosilane (MTS) or trichlorosilane (TCS). The gas material may include silane (SiH₄), ethylene (C₂H₄), and hydrogen chloride (HCl), or SiH₄, propane (C₃H₈), and HCl. In addition, H₂ may be further included as a carrier gas.

In the first process, a ratio of the raw material supplied to the susceptor may be properly adjusted. That is, in the first process, the raw material may be supplied to the susceptor with a flux of the first input quantity, and an atomic and/or molecular ratio of raw materials supplied to the susceptor and ionized in the susceptor may be properly adjusted. More specifically, in the first process, a ratio of the number of carbon atoms to the number of silicon atoms (C/Si) may be 0.7 or less. In addition, a percentage of the silicon atoms to hydrogen molecules (Si/H₂) may be 0.01% or less.

Further, in the second process, the ratio of the number of carbon atoms to the number of silicon atoms (C/Si) may be 0.7 to 1.5. In addition, the percentage of the silicon atoms to the hydrogen molecules (Si/H₂) may be 0.01% or more.

Growth rates in the first process and the second process may differ according to the first input quantity and the second input quantity of the raw material supplied into the susceptor. More specifically, a growth rate in the first process may be lower than that in the second process. More specifically, the growth rate in the first process may be 1/20 to ½ of that in the second process.

In the method of fabricating an epi-wafer according to the embodiment of the present invention, the growth rates may be varied in the first process and the second process by controlling the amount of the raw material supplied to the susceptor.

That is, the input quantity of the raw material in the first process may be controlled to be in the range of 1/10 to ½ of that in the second process, and the growth rate in the first process may be controlled to be in the range of 1/20 to ½ of that in the second process.

In the first process, surface defects on the wafer may be reduced. Normally, there may be defects, such as BPD, EPD, or MPD, on a silicon carbide wafer. Such defects may generate defects on a surface of an epi-layer when the epi-layer is grown on the wafer, degrade final quality of the silicon carbide epi-wafer, and lower efficiency when the silicon carbide epi-wafer is applied to power devices.

According to the method of fabricating an epi-wafer according to the embodiment of the present invention, surface defects on the surface of the wafer may be reduced by reducing the flux of the raw material supplied in the first process and lowering the growth rate in the first process, compared to a normal growth process. Preferably, the surface defects of the wafer may be reduced to about 1 ea/cm² or less. Next, the epi-layer may be deposited in the second process to reduce the surface defects on the final silicon carbide epi-wafer.

Therefore, the final silicon carbide epi-wafer fabricated by the method of fabricating an epi-wafer according to the embodiment of the present invention may have reduced surface defects and high quality.

In the second process, after removing the surface defects on the wafer, the silicon carbide epi-layer may be deposited on the wafer.

The epi-layer may be deposited on the wafer using a deposition apparatus including the susceptor.

FIGS. 2 to 4 are respectively an exploded perspective view, a perspective view, and a cross-sectional view of a susceptor for describing a method of fabricating an epi-wafer according to an embodiment of the present invention.

Referring to FIGS. 2 to 4, the deposition apparatus includes a chamber 10, a susceptor 20, a source gas line 40, a wafer holder 30, and an induction coil 50.

The chamber 10 may have a cylindrical tube shape. Otherwise, the chamber 10 may have a rectangular box shape. The chamber 10 may accommodate the susceptor 20, the source gas line 40, and the wafer holder 30.

In addition, both ends of the chamber 10 may be closed, and external gases may be prevented from flowing into the chamber 10 to maintain a vacuum state. The chamber 10 may include quartz having high mechanical strength and superior chemical endurance. Further, the chamber 10 may have an improved thermal resistance.

In addition, the chamber 10 may further include an insulation unit 60. The insulation unit 60 may function to maintain heat in the chamber 10. Nitride ceramics, carbide ceramics, or graphite may be exemplarily used as the insulation unit 60.

The susceptor 20 may be disposed in the chamber 10. The susceptor 20 may accommodate the source gas line 40 and the wafer holder 30. In addition, the susceptor 20 may accommodate a substrate such as the wafer W. Further, the reaction gas may flow into the susceptor 20 through the source gas line 40.

As illustrated in FIG. 2, the susceptor 20 may include a susceptor top plate 21, a susceptor bottom plate 22, and susceptor side plates 23. In addition, the susceptor top plate 21 may be disposed to face the susceptor bottom plate 22.

The susceptor 20 may be fabricated by disposing the susceptor top plate 21 and the susceptor bottom plate 22, disposing the susceptor side plates 23 at both sides thereof, and bonding the susceptor top plate 21, the susceptor bottom plate 22, and the susceptor side plates 23.

However, the present invention is not limited thereto, and the susceptor 20 may be produced by forming a space for a gas path in the rectangular susceptor 20.

The susceptor 20 may include graphite which has high thermal resistance and is easy to process. In addition, the susceptor 20 may have a structure in which a graphite body is coated with silicon carbide. Further, the susceptor 20 may be heated by induction.

The reaction gas, that is a material supplied to the susceptor 20, may be decomposed into an intermediate compound by heat, and deposited on the wafer W in the intermediate compound state. For example, the material may include a liquid, gas, or solid material including C and Si. The liquid material may include methyltrichlorosilane (MTS) or trichlorosilane (TCS). The gas material may include silane (SiH₄), ethylene (C₂H₄), and HCl, or silane, propane (C₃H₈), and HCl. In addition, H₂ may be further included as a carrier gas.

The material may be decomposed into radicals including Si, C, or Cl, and the silicon carbide epi-layer may be grown on the wafer W. More specifically, the radicals may be CHₓ (1≦x<4) or SiClₓ (1≦x<4) including CH₃, SiCl, SiCl₂, SiHCl, SiHCl₂, or the like.

The source gas line 40 may have a rectangular tube shape. A material used as the source gas line 40 may be, for example, quartz.

The wafer holder 30 may be disposed in the susceptor 20. More specifically, the wafer holder 30 may be disposed behind the susceptor 20 in a direction in which the source gas flows. The wafer holder 30 supports the wafer W. A material used as the wafer holder 30 may be, for example, SIC or graphite.

The induction coil 50 may be disposed on an outer side of the chamber 10. More specifically, the induction coil 50 may surround an outer circumference of the chamber 10. The induction coil 50 may heat the susceptor 20 by electromagnetic induction. The induction coil 50 may be wound around the outer circumference of the chamber 10.

The susceptor 20 may be heated to a temperature of about 1500° C. to about 1700° C. by the induction coil 50. That is, the susceptor 20 may be heated to a growth temperature of the epi-layer by the induction coil 50. Next, the source gas may be decomposed into the intermediate compound at the temperature of 1500° C. to 1700° C. and flow into the susceptor to be sprayed on the wafer W. The silicon carbide epi-layer may be formed on the wafer W by the sprayed radicals.

In such a manner, the silicon carbide epi-layer deposition apparatus according to the embodiment of the present invention may form a thin film such as the epi-layer on a substrate such as the wafer W, and discharge remaining gases through a discharge line disposed on an ending portion of the susceptor 20.

As described above, in the method of fabricating an epi-wafer according to the embodiment of the present invention, surface defects on the surface of the wafer may be reduced by reducing the flux of the raw material supplied in the first process and lowering the growth rate in the first process compared to a normal growth process. Preferably, the surface defects of the wafer may be reduced to about 1 ea/cm² or less. Next, the epi-layer may be deposited in the second process to reduce the surface defects on the final silicon carbide epi-wafer.

Therefore, the final silicon carbide epi-wafer fabricated by the method of fabricating an epi-wafer according to the embodiment of the present invention may have reduced surface defects and high quality.

Hereinafter, embodiments of the present invention will be described in more detail through methods of fabricating a silicon carbide epi-wafer according to Embodiments and Comparative Examples. Such manufacturing examples are only examples for describing the embodiments of the present invention in more detail, and accordingly the present invention is not limited thereto.

### Embodiment

A silicon carbide wafer was disposed in a susceptor, and SiH₄, C₂H₄, HCl, and H were supplied as a source gas into the susceptor. Here, the epi-wafer was fabricated at a temperature of about 1570° C. in a first process and at a temperature of about 1600° C. in a second process.

Here, in the first process, a ratio of the number of carbon atoms to the number of silicon atoms (C/Si) may be 0.7, and a percentage of the silicon atoms to hydrogen molecules (Si/H₂) may be 0.01%.

In addition, an input quantity of the raw material in the first process is 1/10 of that in the second process.

### Comparative Example

A silicon carbide epi-wafer was fabricated using the same method as in the Embodiment, except that the first process was not carried out.

TABLE 1

| | Surface defects (ea/cm²) |
|---|---|
| Embodiment | Less than 1 |
| Comparative Example | More than 1 |

Referring to Table 1, the silicon carbide epi-wafer fabricated according to the Embodiment has fewer surface defects than the silicon carbide epi-wafer fabricated according to the Comparative Example. That is, the surface defects on the surface of the silicon carbide epi-wafer fabricated according to Embodiment are 1 ea/cm², that is, there are hardly any.

That is, in the method of fabricating an epi-wafer according to the embodiment of the present invention, since an epi-layer is grown on the wafer after reducing surface defects on the wafer by changing the input quantity of a raw material, the final epi-wafer may have few surface defects and have high quality and high efficiency.

The characteristics, structures, and effects of the above-described embodiment may be applied to at least one embodiment, and are not limited to the one embodiment. Further, the characteristics, structures, and effects of the above-described embodiment may be combined with other embodiments or modified by one of ordinary skill in the art to which this invention belongs.

Those descriptions related to such combinations and modifications should be interpreted as being included in the scope of the embodiments of the present invention.

It will be apparent to those skilled in the art that various modifications can be made to the above-described exemplary embodiments of the present invention without departing from the spirit or scope of the invention. Thus, it is intended that the present invention cover all such modifications provided they come within the scope of the appended claims and their equivalents.

1. An epi-wafer comprising:
a wafer; and
an epi-layer formed on the wafer,
wherein surface defects of the epi-layer are 1 ea/cm² or less.

2. The epi-wafer of claim 1, wherein the epi-layer includes a first epi-layer and a second epi-layer.

3. The epi-wafer of claim 2, wherein the wafer, the first epi-layer, and the second epi-layer include silicon carbide.
